(19) United States
(12) Patent Application Publication
(10) Pub. No.: US 2013/0075243 A1
(43) Pub. Date: Mar. 28, 2013

(54) SWITCH DEVICE, DISPLAY WITH SWITCH DEVICE, AND ELECTRONIC UNIT WITH SWITCH DEVICE

(71) Applicants: Naofumi Tsuchiya, Kanagawa (JP); Makoto Koizumi, Tokyo (JP); Hiroyuki Ono, Tokyo (JP)

(72) Inventors: Naofumi Tsuchiya, Kanagawa (JP); Makoto Koizumi, Tokyo (JP); Hiroyuki Ono, Tokyo (JP)

(73) Assignee: Sony Corporation, Tokyo (JP)

(21) Appl. No.: 13/608,374

(22) Filed: Sep. 10, 2012

(30) Foreign Application Priority Data
Sep. 26, 2011 (JP) 2011-209252

(51) Int. Cl. H01H 13/14; H03K 17/975

(52) U.S. Cl. 200/600; 200/341

(57) ABSTRACT

A switch device includes: a switch; an operation section disposed to face the switch; a first resilient section that is deformed by first pressing force derived from the operation section; and a second resilient section that is brought into contact with the switch by the deformation of the first resilient section, and is deformed to activate the switch by second pressing force greater than the first pressing force.

### CROSS-REFERENCE TO RELATED APPLICATION

The present application claims priority from Japanese Patent Application No. JP 2011-209252 filed in the Japanese Patent Office on Sep. 26, 2011, the entire content of which is incorporated herein by reference.

### BACKGROUND

The present disclosure relates to a switch device, a display with the switch device, and an electronic unit with the switch device.

In switch devices, as disclosed in Japanese Unexamined Patent Application Publication No. 2005-339876 for example, a base section is provided behind a key top (operation section), and a tact switch (switch) is disposed under the base section. When the key top is pressed, then, in conjunction with this, the base section presses a button of the tact switch to conduct electricity.

### SUMMARY

In such switch devices as disclosed in Japanese Unexamined Patent Application Publication No. 2005-339876, however, since pressing force applied to a key top is directly transmitted to a button through a base section, excessive pressing force may break the button.

It is to be noted that, in Japanese Unexamined Patent Application Publication No. 2005-339876, a rib is provided in a peripheral portion of the base section, and this rib is brought into contact with a portion other than the button of the tact switch, thereby preventing the key top from being pressed more than a stroke of the button. However, since there is a possibility that a clearance between the base section and the button is varied by accumulation of factors such as assembly error and dimensional tolerance, it has been difficult to completely prevent the breakage of the button in some cases even when the rib, such as that disclosed in Japanese Unexamined Patent Application Publication No. 2005-339876, is provided. For example, when the above-described clearance becomes very small, the base section may touch the button before the rib contacts the portion other than the button of the tact switch even when the rib is provided as disclosed in Japanese Unexamined Patent Application Publication No. 2005-339876, and the button may be consequently broken by excessive force applied thereto.

It is desirable to provide a switch device which makes it possible to prevent breakage of a switch and to absorb variation of a clearance between the switch and a component configured to activate the switch, and to provide a display and an electronic unit each including the switch device.

A switch device according to an embodiment of the present disclosure includes: a switch; an operation section disposed to face the switch; a first resilient section that is deformed by first pressing force derived from the operation section; and a second resilient section that is brought into contact with the switch by the deformation of the first resilient section, and is deformed to activate the switch by second pressing force greater than the first pressing force.

A display of according to an embodiment of the present disclosure is provided with a switch device. The switch device includes: a switch; an operation section disposed to face the switch; a first resilient section that is deformed by first pressing force derived from the operation section; and a second resilient section that is brought into contact with the switch by the deformation of the first resilient section, and is deformed to activate the switch by second pressing force greater than the first pressing force.

An electronic unit according to an embodiment of the present disclosure is provided with a switch device. The switch device includes: a switch; an operation section disposed to face the switch; a first resilient section that is deformed by first pressing force derived from the operation section; and a second resilient section that is brought into contact with the switch by the deformation of the first resilient section, and is deformed to activate the switch by second pressing force greater than the first pressing force.

In the switch device of the embodiment of the present disclosure, when the operation section is pressed with the first pressing force, the first resilient section is deformed. With this deformation of the first resilient section, the second resilient section is brought into contact with the switch. Further, when the operation section is pressed with the second pressing force greater than the first pressing force, the second resilient section is deformed to activate the switch. At this time, the second pressing force derived from the operation section is transmitted to the switch through the second resilient section. Consequently, an existing issue where force applied to a key top is directly and wholly transmitted to a button of a tact switch through a base section is improved, and it is possible to prevent breakage of the switch due to excessive pressing force. In addition, by adjusting a stroke of the second resilient section, it is possible to absorb variation of a clearance between the switch and the second resilient section that activates the switch.

In the display and the electronic unit according to the respective embodiments of the present disclosure, operation such as, but not limited to, turning on or off of the power of a main body section is performed by the switch device according to the embodiment of the present disclosure.

According to the switch device of the embodiment of the present disclosure, the pressing force derived from the operation section is transmitted to the switch through the two stages of the first resilient section and the second resilient section. Thus, it is possible to prevent breakage of the switch due to excessive pressing force, and to absorb variation of the clearance between the switch and the second resilient section that activates the switch. Hence, by incorporating the switch device according to the embodiment of the present disclosure in each of the display and the electronic unit, it is possible to prevent breakage of the switch device and to enhance the reliability thereof, even when unintended excessive force is applied to the switch device, such as at the time of an assembly work or the like for example.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a perspective view showing an external appearance of a display according to an embodiment of the present disclosure.

FIG. 2 is a plan view showing a configuration of a switch device illustrated in FIG. 1.

FIGS. 3A to 3C are plan views for describing an operation of the switch device illustrated in FIG. 2.

FIG. 4 is a plan view showing a configuration of a switch device in the case where a second resilient section is not provided thereto according to a comparative example.

FIG. 5 is a sectional view showing a configuration of a switch device according to a first modification.

FIG. 6 is a sectional view showing a configuration of a switch device according to a second modification.

FIG. 7 is a sectional view showing a configuration of a switch device according to a third modification.

FIG. 8 is a perspective view showing an external appearance of an application example 1.

### DETAILED DESCRIPTION

Referring to the figures, an embodiment of the present disclosure will be described in detail. Description will be given in the following order.

1. Embodiment (an example where a switch is a mechanical switch)

2. First modification (an example where a switch is upwardly mounted on a substrate)

3. Second modification (an example where a second resilient section is configured of a plate spring)

4. Third modification (an example where a switch is a capacitance type switch or a pressure-sensitive type switch)

5. Application example

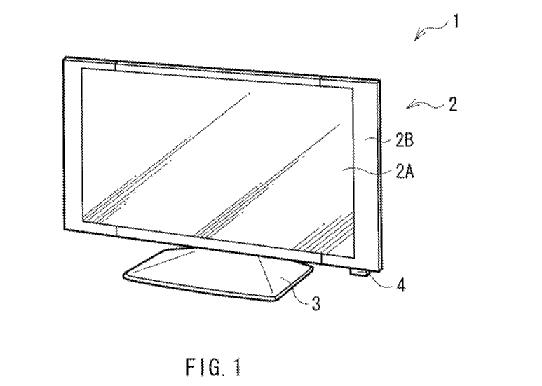

FIG. 1 shows an external appearance of a display (television) including a switch device according to an embodiment of the present disclosure. This display 1 has, for example, a configuration in which a main body section 2 having a thin-plate shape for image display is supported by a supporting section (stand) 3. The main body section 2 is, for example, a section in which a display panel 2A of liquid crystal or the like is housed in an exterior member 2B. It is to be noted that, the display panel 2A may also be configured of an alternative display panel such as an organic EL (electroluminescence) panel and a plasma display panel, other than a liquid crystal display panel.

The main body section 2 is provided with a switch device 4 used to turn on or off the power. The position at which the switch device 4 is attached to the main body section 2 is not specifically limited and may be a top face, a left side face, a right side face, or a bottom face of the main body section 2, but preferably the switch device 4 is provided on a right side of the bottom face of the main body section 2, for example. In addition, preferably, the switch device 4 is provided in the vicinity of an LED (light emitting diode) that indicates the operation state of the main body section 2 and a reception section of a remote controller. One reason is that such a configuration makes it possible to provide the switch device 4, the LED, and the reception section on the same substrate, and to reduce the number of components such as a cable.

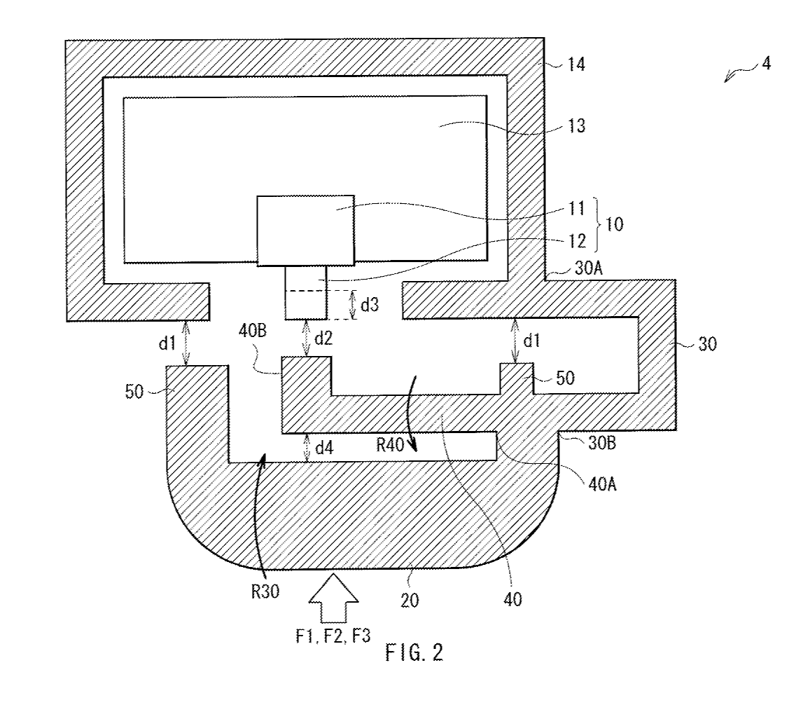

FIG. 2 shows a configuration of the switch device 4 illustrated in FIG. 1. The switch device 4 includes, for example, a switch 10, an operation section 20, a first resilient section 30, and a second resilient section 40. The switch 10 is, for example, a mechanical switch including a switch main body 11 and a button 12, and an on/off operation is performed when the button 12 is pressed into the switch main body 11. The operation section 20 is a press button disposed to face the switch 10. The first resilient section 30 is deformed by first pressing force F1 from the operation section 20. The second resilient section 40 is brought into contact with the button 12 of the switch 10 by deformation of the first resilient section 30, and is deformed by second pressing force F2 greater than the first pressing force F1 to activate the switch 10. With this configuration, in the display 1, breakage of the switch 10 is prevented, and variation of clearance d2 between the button 12 of the switch 10 and the second resilient section 40 is absorbed.

The switch 10 is mounted on a substrate 13. The switch 10 and the substrate 13 are housed in a housing (holder) 14. For example, the housing 14 is made of a resin material such as PC resin (polycarbonate resin), PC resin mixed with ABS resin (acrylonitrile-butadiene-styrene resin), PS (polystyrene), and ABS resin.

The operation section 20 is connected to the housing 14 by the first resilient section 30. The operation section 20 and the first resilient section 30 are, for example, made of the above-described resin material and are integrally formed with the housing 14. It is to be noted that, as illustrated in FIG. 1, a majority of portions of the switch device 4 are covered by the exterior member 2B, and only the operation section 20 can be seen from the outside of the main body section 2.

The first resilient section 30 has, for example, a hinge structure, and one end (fixing end) 30A thereof is fixed to the housing 14, and the other end (movable end) 30B thereof is connected to the operation section 20. With this configuration, the first resilient section 30 allows the movable end 30B and the operation section 20 to be moveably displaced to the switch 10 side (along an arrow R30 direction) around the fixing end 30A serving as a pivot. It is to be noted that, while the first resilient section 30 has a rectangular shape composed of three sides in FIG. 2 for example, the shape of the first resilient section 30 is not limited the shape illustrated in FIG. 2, and the first resilient section 30 may be appropriately formed according to a positional relationship between the fixing end 30A and the operation section 20.

The second resilient section 40 has, for example, a hinge structure, and one end (fixing end) 40A thereof is fixed to the first resilient section 30, and the other end (movable end) 40B thereof faces the button 12 of the switch 10. With this configuration, the second resilient section 40 allows the movable end 40B to be moveably displaced to the operation section 20 side (along an arrow R40 direction) around the fixing end 40A serving as a pivot.

It is preferable that the form and the size (such as length, thickness, and width) of the second resilient section 40 be so adjusted that the second resilient section 40 is not deformed by the pressing force necessary for the operation of the switch 10, but is deformed by force smaller than the fracture load of the button 12 of the switch 10. It is to be noted that, while the second resilient section 40 is formed in an L-shape in FIG. 2 for example, the shape of the second resilient section 40 is not limited to the shape illustrated in FIG. 2, and the second resilient section 40 may be appropriately formed according to a positional relationship between the fixing end 40A and the button 12 of the switch 10. Similarly to the operation section 20 and the first resilient section 30, it is preferable that the second resilient section be made of the above-described resin material and be integrally formed with the housing 14, for example.

The operation section 20 is preferably formed with a protruding section 50 protruding toward the housing 14. The protruding section 50 is brought into contact with both the operation section 20 and the housing 14 by the third pressing force F3 greater than the second pressing force F2. With this configuration, when excessive pressing force is applied, it is possible to receive that force by the protruding section 50, and to prevent further deformation of the second resilient section 40. Consequently, it is possible to prevent transmission of excessive pressing force to the switch 10 through the second resilient section 40, and to avoid breakage of the switch 10.

Preferably, a clearance d1 between the protruding section 50 and the housing 14, a clearance d2 between the second resilient section 40 and the button 12, and a stroke d3 of the button 12 satisfy d1≧d2+d3. With this configuration, even when the clearance d2 is increased due to accumulation of factors such as assembly error and dimensional tolerance, it is possible to press the button 12 of the switch 10.

In addition, preferably, a stroke d4 of the second resilient section 40 satisfies d1−(d2+d3)<d4 (where d1 represents a clearance between the protruding section 50 and the housing 14, d2 represents a clearance between the second resilient section 40 and the button 12, and d3 represents a stroke of the button 12). With this configuration, even when the clearance d2 is decreased due to accumulation of factors such as assembly error and dimensional tolerance, it is possible to avoid breakage of the switch 10.

For example, the switch device 4 operates as follows.

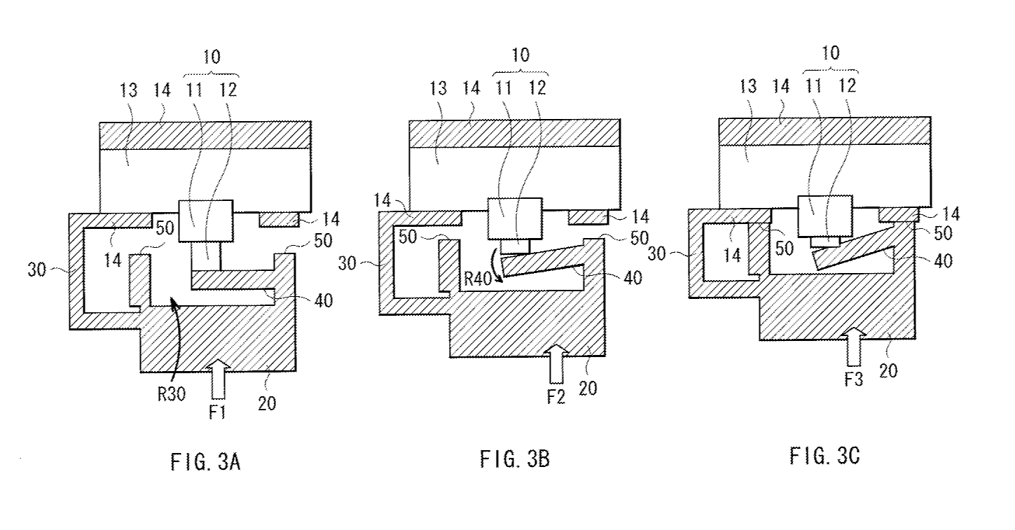

First, as illustrated in FIG. 3A, when the operation section 20 is pressed with the first pressing force F1, the first resilient section 30 is deformed and deflected to the switch 10 side (along an arrow R30 direction). With this deflection of the first resilient section 30, the second resilient section 40 is brought into contact with the button 12 of the switch 10.

Further, as illustrated in FIG. 3B, when the operation section 20 is pressed with the second pressing force F2 greater than the first pressing force F1, the second resilient section 40 is deformed and deflected to the operation section 20 side (along an arrow R40 direction) to press the button 12 into the switch main body 11, thereby activating the switch 10.

Furthermore, as illustrated in FIG. 3C, when the operation section 20 is pressed with the third pressing force F3 greater than the second pressing force F2, the protruding section 50 contacts the housing 14 to inhibit further deflection of the second resilient section 40. With this configuration, when the excessive pressing force F3 is applied, the pressing force F3 is received by the protruding section 50, making it possible to prevent transmission of the excessive pressing force F3 to the switch 10 through the second resilient section 40, and to avoid breakage of the switch 10.

In the present embodiment, since the second resilient section 40 is provided, the second pressing force F2 derived from the operation section 20 is transmitted to the button 12 of the switch 10 through the second resilient section 40. Consequently, an existing issue where the force applied to a key top is directly and wholly transmitted to a button of a tact switch through a base section is improved. Hence, it is possible to prevent breakage of the switch 10 when strong pressing force beyond a regular range of use is applied thereto. In addition, by adjusting the stroke d4 of the second resilient section 40, it is possible to absorb variation of the clearance d2 between the button 12 of the switch 10 and the second resilient section 40.

The absorption of the clearance d2 by adjusting the stroke d4 of the second resilient section 40 will be described below.

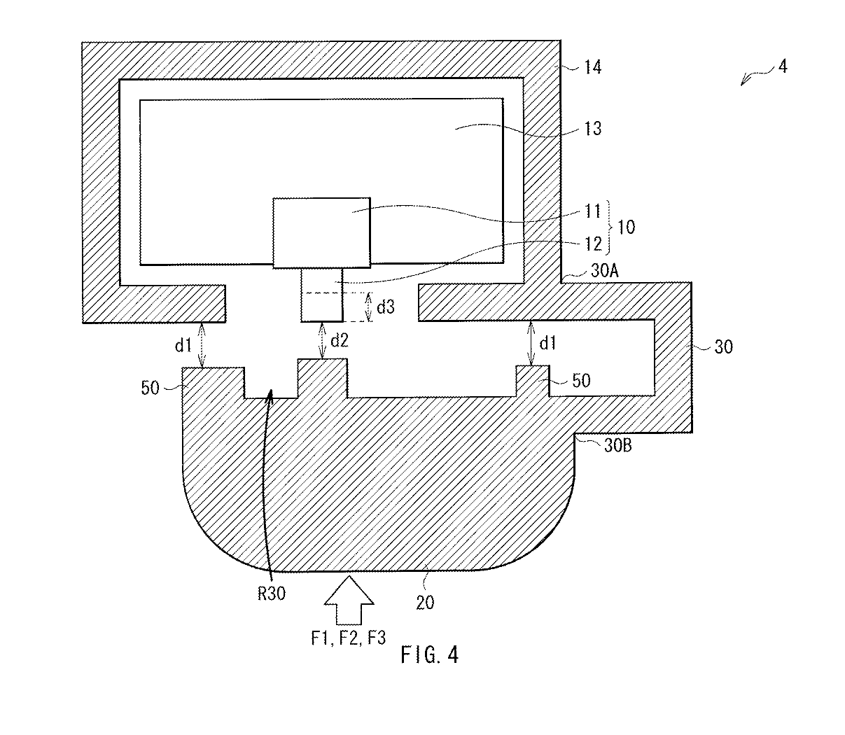

In the case where the second resilient section 40 is not provided as illustrated in FIG. 4 according to a comparative example, it is sufficient if d1=d2+d3 is typically satisfied (where d1 represents a clearance between the protruding section 50 and the housing 14, d2 represents a clearance between the operation section 20 and the button 12, and d3 represents a stroke of the button 12).

However, in practice, the clearance d2 is varied by tolerance of the housing 14, the external shape of the substrate 13, mounting of the switch 10, and the like. As a result, for example, in the case where the clearance d2 is decreased and thus d1>d2+d3 is established, it becomes difficult for the protruding section 50 to contact with the housing 14 even when the operation section 20 has already touched the button 12 of the switch 10. Therefore, there is a possibility that excessive forth is applied to the switch 10 when the operation section 20 is pressed with strong force. In addition, in the case where the clearance d2 is increased and thus d1<d2+d3 is established, the protruding section 50 may contact the housing 14 in advance even when the operation section 20 has not yet touched the button 12 of the switch 10. Therefore, there is a possibility that the button 12 of the switch 10 may not be pressed.

In contrast, in the present embodiment, the second resilient section 40 is provided. Thus, with the stroke d4 of the second resilient section 40, it is possible to absorb variation of the clearance d2 due to accumulation of factors such as assembly error and dimensional tolerance, and to avoid breakage of the switch 10. That is, when the clearance d2 is increased to a maximum value, setting the clearance d1 between the protruding section 50 and the housing 14 so as to satisfy d1≧d2+d3 makes it possible to avoid the situation that the button 12 of the switch 10 may not be pressed. Conversely, when the clearance d2 is decreased to a minimum value, setting the stroke d4 of the second resilient section 40 so as to satisfy d1−(d2+d3)<d4 makes it possible to prevent breakage of the switch 10 even when the operation section 20 is pressed with strong force beyond a regular range of use.

It is assumed that the wording “regular range of use” as used herein refers to, for example, pressing force applied to the operation section 20 when a user presses the operation section 20 with his or her finger (for example, about several kilograms). On the other hand, examples of “the case where strong pressing force beyond a regular range of use may be applied to the switch 10” include a possibility that, in the case where the switch device 4 is provided on the bottom face of the main body section 2 as illustrated in FIG. 1, the operation section 20 is pressed by the own weight of the main body section 2 (several tens of kilograms or more) when the main body section 2 is placed on the floor in order to attach the main body section 2 to the stand 3. In the present embodiment, even when such unintended strong force is applied to the switch 10, breakage of the switch 10 is prevented. Consequently, it is possible to prevent breakage of the switch device 4, and to enhance the reliability of the display 1.

As described, since, in the present embodiment, the pressing force F1 and the pressing force F2 from the operation section 20 are transmitted to the switch 10 through the two stages of the first resilient section 30 and the second resilient section 40, it is possible to prevent breakage of the switch 10 due to excessive pressing force, and to absorb variation of the clearance d2 between the switch 10 and the second resilient section 40 that activates the switch 10.

It is to be noted that, while an example where the protruding section 50 protrudes from the operation section 20 toward the housing 14 is described in the above-mentioned embodiment, the protruding section 50 may also protrude from the housing 14 toward the operation section 20.

### First Modification

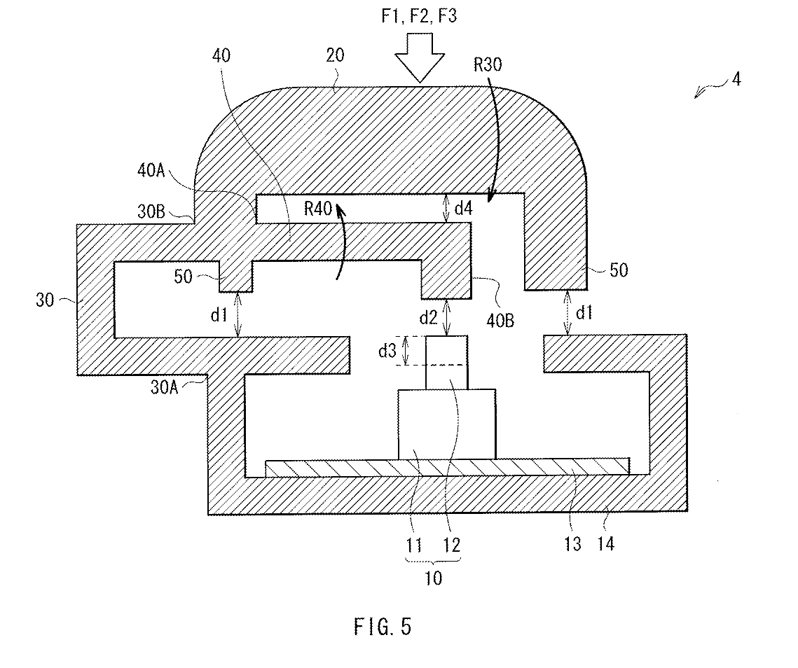

In addition, while the switch 10 is mounted sideways on the substrate 13 in the above-mentioned embodiment, the switch 10 may also be upwardly mounted on the substrate 13 as illustrated in FIG. 5.

### Second Modification

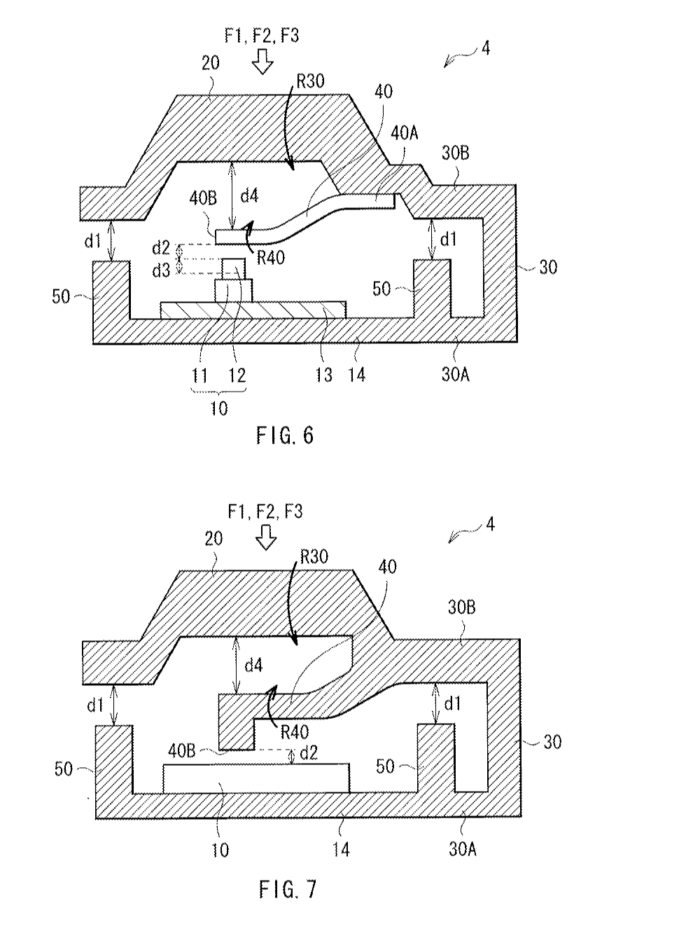

Further, while the second resilient section 40 has a hinge structure in the above-mentioned embodiment, the second resilient section 40 may also be configured of a plate spring as illustrated in FIG. 6. It is to be noted that, in FIG. 6, the switch 10 is upwardly mounted on the substrate 13 as is the case with the first modification.

### Third Modification

FIG. 7 shows a configuration of the switch device 4 according to a third modification of the present disclosure. In this modification, the switch 10 is configured of a capacitance type switch or a pressure-sensitive type switch. In addition, as is the case with the first modification, the switch 10 is upwardly mounted on the substrate 13. Except for these points, the switch device 4 has a configuration, a function, and an effect similar to those of the above-mentioned embodiment.

In the present modification, unlike the above-mentioned embodiment, since the switch 10 is not provided with the button 12, the stroke d3 of the button 12 is zero (d3=0). Therefore, preferably, the clearance d1 between the protruding section 50 and the housing 14, and the clearance d2 between the second resilient section 40 and the switch 10 satisfy d1≧d2. One reason for this is similar to that of the above-mentioned embodiment.

In addition, preferably, the stroke d4 of the second resilient section 40 satisfies d1−d2<d4 (where d1 represents the clearance between the protruding section 50 and the housing 14, and d2 represents the clearance between the second resilient section 40 and the switch 10). One reason for this is similar to that of the above-mentioned embodiment.

### Application Example

Next, an application example of the switch device 4 of the above-mentioned embodiment will be described. The switch device 4 may be applied to electronic units in various fields such as personal computers, mobile terminals including mobile phones, smart phones, and the like, and imaging devices including digital still cameras, video camcorders, and the like, as well as the above-described television. In other words, the switch device 4 may be applied to electronic units in various fields which display an externally inputted video signal or an internally generated video signal as an image or a video. In addition, the switch device 4 may also be applied to other electronic units and electric units which do not perform display such as lighting fixtures, intercoms, and game controllers.

### Application Example 1

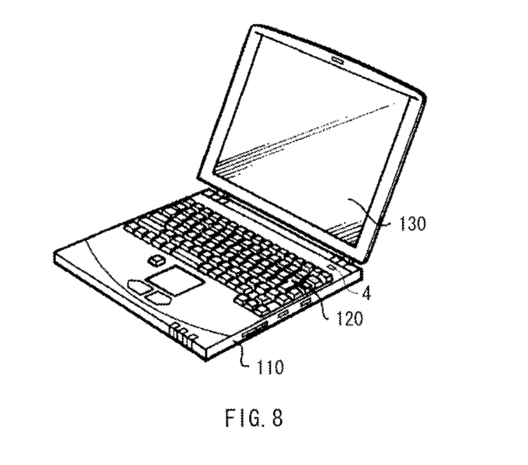

FIG. 8 shows an external appearance of a notebook personal computer to which the switch device 4 of the above-mentioned embodiment is applied. This notebook personal computer includes, for example, a main body section 110, a keyboard 120 used to input letters and the like, and a display section 130 configured to display an image. For example, the main body section 110 is provided with the switch device 4 of the above-mentioned embodiment.

Hereinabove, while the present disclosure has been described based on the embodiment, the present disclosure is not limited to the above-mentioned embodiment, and various modifications may be made. For example, the material, the thickness, and the like of the configuration elements described in the above-mentioned embodiment are not restrictive, and other materials and thicknesses may also be adopted.

In addition, for example, while the configuration of the display (television) has been specifically described in the above-mentioned embodiment, all of the configuration elements do not have to be included, and in addition, other configuration elements may further be included.

Accordingly, it is possible to achieve at least the following configurations from the above-described example embodiments, the modifications, and the application examples of the disclosure.

(1) A switch device, including:

a switch;

an operation section disposed to face the switch;

a first resilient section that is deformed by first pressing force derived from the operation section; and

a second resilient section that is brought into contact with the switch by the deformation of the first resilient section, and is deformed to activate the switch by second pressing force greater than the first pressing force.

(2) The switch device according to (1), further including:

a housing that houses the switch; and

a protruding section that protrudes from one of the operation section and the housing toward the other of the operation section and the housing, and is brought into contact with both the operation section and the housing by third pressing force greater than the second pressing force.

(3) The switch device according to (1) or (2), wherein the second resilient section is adjusted to have a form and a size with which the second resilient section fails to be deformed by pressing force necessary to operate the switch, and with which the second resilient section is deformed by force smaller than a fracture load of the switch.

(4) The switch device according to any one of (1) to (3), wherein the switch is a mechanical switch that includes a switch main body and a button.

(5) The switch device according to (4), wherein the following conditional expression is satisfied:

d1≧d2+d3

where d1 is a clearance between the protruding section and the housing, d2 is a clearance between the second resilient section and the button, and d3 is a stroke of the button.

(6) The switch device according to (5), wherein the following conditional expression is satisfied for a stroke d4 of the second resilient section:

d1−(d2+d3)<d4

where d1 is the clearance between the protruding section and the housing, d2 is the clearance between the second resilient section and the button, and d3 is the stroke of the button.

(7) The switch device according to any one of (1) to (3), wherein the switch is one of a capacitance type switch and a pressure-sensitive type switch.

(8) The switch device according to (7), wherein the following conditional expression is satisfiled:

d1≧d2

where d1 is a clearance between the protruding section and the housing, and d2 is a clearance between the second resilient section and the switch.

(9) The switch device according to (8), wherein the following conditional expression is satisfied for a stroke d4 of the second resilient section:

d1−d2<d4

where d1 is the clearance between the protruding section and the housing, and d2 is the clearance between the second resilient section and the switch.

(10) The switch device according to any one of (1) to (9), wherein the second resilient section has a hinge structure.

(11) The switch device according to any one of (1) to (9), wherein the second resilient section includes a plate spring.

(12) A display with a switch device, the switch device including:

a switch;

an operation section disposed to face the switch;

a first resilient section that is deformed by first pressing force derived from the operation section; and

a second resilient section that is brought into contact with the switch by the deformation of the first resilient section, and is deformed to activate the switch by second pressing force greater than the first pressing force.

(13) An electronic unit with a switch device, the switch device including:

a switch;

an operation section disposed to face the switch;

a first resilient section that is deformed by first pressing force derived from the operation section; and

a second resilient section that is brought into contact with the switch by the deformation of the first resilient section, and is deformed to activate the switch by second pressing force greater than the first pressing force.

It should be understood by those skilled in the art that various modifications, combinations, sub-combinations and alterations may occur depending on design requirements and other factors insofar as they are within the scope of the appended claims or the equivalents thereof.

What is claimed is:

1. A switch device, comprising:
a switch;
an operation section disposed to face the switch;
a first resilient section that is deformed by first pressing force derived from the operation section; and
a second resilient section that is brought into contact with the switch by the deformation of the first resilient section, and is deformed to activate the switch by second pressing force greater than the first pressing force.

2. The switch device according to claim 1, further comprising:
a housing that houses the switch; and
a protruding section that protrudes from one of the operation section and the housing toward the other of the operation section and the housing, and is brought into contact with both the operation section and the housing by third pressing force greater than the second pressing force.

3. The switch device according to claim 1, wherein the second resilient section is adjusted to have a form and a size with which the second resilient section fails to be deformed by pressing force necessary to operate the switch, and with which the second resilient section is deformed by force smaller than a fracture load of the switch.

4. The switch device according to claim 2, wherein the switch is a mechanical switch that includes a switch main body and a button.

5. The switch device according to claim 4, wherein the following conditional expression is satisfied:
d1≧d2+d3
where d1 is a clearance between the protruding section and the housing, d2 is a clearance between the second resilient section and the button, and d3 is a stroke of the button.

6. The switch device according to claim 5, wherein the following conditional expression is satisfied for a stroke d4 of the second resilient section:
d1−(d2+d3)<d4
where d1 is the clearance between the protruding section and the housing, d2 is the clearance between the second resilient section and the button, and d3 is the stroke of the button.

7. The switch device according to claim 2, wherein the switch is one of a capacitance type switch and a pressure-sensitive type switch.

8. The switch device according to claim 7, wherein the following conditional expression is satisfiled:
d1≧d2
where d1 is a clearance between the protruding section and the housing, and d2 is a clearance between the second resilient section and the switch.

9. The switch device according to claim 8, wherein the following conditional expression is satisfied for a stroke d4 of the second resilient section:
d1−d2<d4
where d1 is the clearance between the protruding section and the housing, and d2 is the clearance between the second resilient section and the switch.

10. The switch device according to claim 1, wherein the second resilient section has a hinge structure.

11. The switch device according to claim 1, wherein the second resilient section includes a plate spring.

12. A display with a switch device, the switch device comprising:
a switch;
an operation section disposed to face the switch;
a first resilient section that is deformed by first pressing force derived from the operation section; and
a second resilient section that is brought into contact with the switch by the deformation of the first resilient section, and is deformed to activate the switch by second pressing force greater than the first pressing force.

13. An electronic unit with a switch device, the switch device comprising:
a switch;
an operation section disposed to face the switch;
a first resilient section that is deformed by first pressing force derived from the operation section; and
a second resilient section that is brought into contact with the switch by the deformation of the first resilient section, and is deformed to activate the switch by second pressing force greater than the first pressing force.
